(19) United States
(12) Patent Application Publication
(10) Pub. No.: US 2025/0137128 A1
(43) Pub. Date: May 1, 2025

(54) PROCESS GAS SUPPLY DEVICE AND SUBSTRATE PROCESSING SYSTEM HAVING THE SAME

(71) Applicant: EUGENE TECHNOLOGY CO., LTD., Yongin-si (KR)

(72) Inventors: In Soo SON, Hwaseong-si (KR); Chang Hun SHIN, Icheon-si (KR); Chan Yong PARK, Icheon-si (KR); Deog Hwan KIM, Yongin-si (KR); Jae Jun JUNG, Seoul (KR); Si Won RYU, Yongin-si (KR); Chang Min PARK, Seoul (KR); Jae Sun KIM, Seoul (KR); Ki Hoon KIM, Suwon-si (KR); Jong Hoon KIM, Hwaseong-si (KR); Jeong Hyeon KIM, Yongin-si (KR); In Seong HWANG, Yongin-si (KR)

(21) Appl. No.: 18/416,832

(22) Filed: Jan. 18, 2024

(30) Foreign Application Priority Data
Oct. 27, 2023 (KR) 10-2023-0145773

(51) Int. Cl. C23C 16/455; H01L 21/67

(52) U.S. Cl. CPC C23C 16/45565; C23C 16/4557; H01L 21/67017

(57) ABSTRACT

Provided are a process gas supply device, which stably controls a temperature of a process gas to supply the process gas, and a substrate processing system including the same. The process gas supply device includes a gas hub to which a process gas is supplied from a gas supply source, a plurality of gas lines branched from the gas hub to transfer the supplied process gas, and an integrated heater part provided to surround the plurality of gas lines and the gas hub so as to heat the gas hub and the plurality of gas lines at the same time.

### CROSS-REFERENCE TO RELATED APPLICATION

This application claims priority to Korean Patent Application No. 10-2023-0145773 filed on Oct. 27, 2023 and all the benefits accruing therefrom under 35 U.S.C. § 119, the contents of which are incorporated by reference in their entirety.

### BACKGROUND

The present disclosure relates to a process gas supply device and a substrate processing system including the same, and more particularly, to a process gas supply device that stably controls a temperature of a process gas to supply the process gas and to a substrate processing system including the same.

In a substrate processing device for manufacturing semiconductors, a process gas is sometimes heated before being supplied to a chamber for stable reaction and particle control.

In the related art, a heating jacket is used to surround each gas line that supplies the process gas and heat each gas line individually. In this case, a problem such as temperature changes in specific portions causes limitations such as particles during the process. That is, when heating the individual gas line by installing the heating jacket, it takes up a lot of space due to space constraints, and not only it is difficult to control heating zones because the number of heating zones increases, but also a temperature varies depending on sections of the heating jacket to cause limitations such as particles.

To solve these limitations, it is necessary to stably maintain a temperature in the entire gas line.

### SUMMARY

The present disclosure provides a process gas supply device that uniformly heats a plurality of gas lines, through which a process gas is supplied, to stably maintain a temperature of a process gas, and a substrate processing system including the same.

In accordance with an exemplary embodiment, a process gas supply device include: a gas hub to which a process gas is supplied from a gas supply source; a plurality of gas lines branched from the gas hub to transfer the supplied process gas; and an integrated heater part provided to surround the plurality of gas lines and the gas hub so as to heat the gas hub and the plurality of gas lines at the same time.

The integrated heater part may include: a thermally conductive block configured to surround the plurality of gas lines and the gas hub; and a heat generating element that is in at least partially contact with the thermally conductive block to heat the thermally conductive block.

The thermally conductive block may include: a hub accommodation part configured to surround the gas hub; and a gas line accommodation part configured to surround the plurality of gas lines.

Each of the plurality of gas lines may include a horizontal line part extending in a radial direction from the gas hub and a vertical line part extending in a direction perpendicular to the radial direction, wherein the gas line accommodation part may include: a first line accommodation part configured to surround the horizontal line part; and a second line accommodation part configured to surround the vertical line part.

The first line accommodation part and the second line accommodation part may have shapes different from each other.

The gas hub may be provided in plurality to be stacked in a vertical direction, and the hub accommodation part may be configured to surround the plurality of gas hubs together.

The plurality of gas lines may be connected to each of the gas hubs, respectively, in the same number, and the gas line accommodation part may be provided in plurality to surround the gas lines disposed in the same direction.

A plurality of gas supply lines through which the process gas is supplied may be connected to the plurality of gas hubs, respectively, and the process gas may include a plurality of gases supplied to the gas hubs different from each other.

The plurality of gas lines may be disposed symmetrically around the gas hub to extend radially.

The thermally conductive block may include aluminum.

The heat generating element may include a cartridge heater.

The process gas supply device may further include a temperature measuring part configured to measure a temperature of the thermally conductive block.

The integrated heater part may further include an insulating part configured to surround the thermally conductive block.

The insulating part may include glass fiber.

In accordance with another exemplary embodiment, a substrate processing system includes: the process gas supply device in accordance with an exemplary embodiment; a plurality of shower heads which are branched from the gas hub and into which the process gas is supplied; and a plurality of substrate supports provided to correspond to the plurality of shower heads, respectively.

The substrate processing system may further include a plurality of sub chambers in which the plurality of shower heads and the plurality of substrate supports are respectively provided in pairs.

The plurality of shower heads may be disposed to be symmetrical to each other.

Each of the gas hubs may be supplied with any one of the process gas.

### BRIEF DESCRIPTION OF THE DRAWINGS

Exemplary embodiments can be understood in more detail from the following description taken in conjunction with the accompanying drawings, in which:

FIG. 1 is a schematic view of a process gas supply device in accordance with an exemplary embodiment;

FIG. 2 is a view of the process gas supply device including a plurality of gas hubs in accordance with an exemplary embodiment;

FIG. 3 is a partial cross-sectional view of a first line accommodation part and a second line accommodation part in accordance with an exemplary embodiment;

FIG. 4 is a schematic view of a substrate processing system in accordance with another exemplary embodiment; and

FIG. 5 is a cross-sectional view of a plurality of sub chambers in accordance with another exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

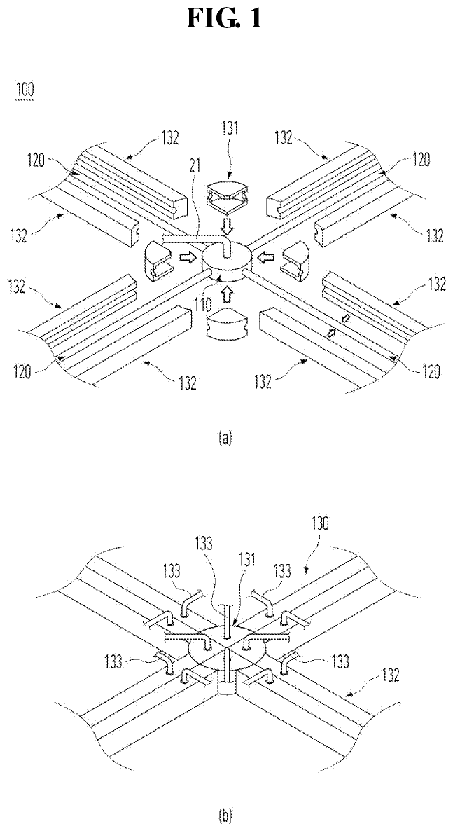

FIG. 1 is a schematic view of a process gas supply device in accordance with an exemplary embodiment. Here, (a) of FIG. 1 is an exploded perspective view of the process gas supply device in accordance with an exemplary embodiment, and (b) of FIG. 1 is a coupling perspective view of the process gas supply device.

Referring to FIG. 1, a process gas supply device 100 in accordance with an exemplary embodiment may include a gas hub 110 to which a process gas is supplied from a gas supply source (not shown), a plurality of gas lines 120 branching from the gas hub 110 to transfer the supplied process gas; and an integrated heater part 130 provided to surround the plurality of gas lines 120 and the gas hub 110 so as to heat the gas hub 110 and the plurality of gas lines 120 at the same time.

The gas hub 110 may receive the process gas from the gas supply source (not shown) and may be connected to a gas supply line 21 so that the process gas is supplied from the gas supply source (not shown) through the gas supply line 21. Here, the gas hub 110 may be filled first (or primarily) with the process gas, and after the process gas is fully (or completely) filled, and an internal pressure becomes uniform throughout, the process gas may be branched from the plurality of gas lines 120 and then be supplied to each of the gas lines 120. For example, the gas hub 110 may have the same number of sub spaces as the number of branched gas lines 120, and each of the sub spaces may communicate with each other so that the process gas supplied from one gas supply line 21 is completely filled and may be partially blocked by partition, etc., so as to be divided. Here, the process gas may be first filled in each sub space and then supplied to each gas line 120 when (or after) pressures of all the sub spaces are the same (or uniform).

The plurality of gas lines 120 may be branched from the gas hub 110, and the process gas branched from the gas hub 110 may be supplied to flow, and the supplied process gas may be transferred to a sub chamber 215 and/or a shower head 210. For example, the gas lines 120 branched from the gas hub 110 may be connected to sub chambers 215 and/or shower heads 210, which are different from each other, and then, a processing process for a substrate 10 may be performed on a process station of each sub chamber 215. Here, the processes may be performed independently in the sub chambers 215, respectively, and the same process may be performed, or different processes may be performed respectively.

The integrated heater part 130 may be provided to surround the plurality of gas lines 120 and the gas hub 110. The integrated heater part 130 may heat the gas hub 110 and the plurality of gas lines 120 at the same time and also uniformly heat the process gas within the gas hub 110 and the plurality of gas lines 120. Thus, the heating uniformity of the plurality of gas lines 120 may be improved, and a temperature of the process gas flowing within the gas hub 110 and the plurality of gas lines 120 may be maintained uniformly and stably at all points within the gas hub 110 and the plurality of gas lines 120. Therefore, the particles generated during the process due to the limitations such as changes in the temperature of the process gas in specific portions within the gas hub 110 and the plurality of gas lines 120 may be prevented, and stable reaction of the process gas may be achieved.

Here, the integrated heater part 130 includes thermally conductive blocks 131 and 132 that surround the plurality of gas lines 120 and the gas hub 110 and a heat generating element 133 that is in at least partially contact with the thermally conductive blocks 131 and 132 to heat the thermally conductive blocks 131 and 132. The thermally conductive blocks 131 and 132 may surround the plurality of gas lines 120 and the gas hub 110 and may be heated by the heat generating element 133 to transfer heat to the plurality of gas lines 120 and the gas hub 110, thereby heating the process gas in the gas hub 110 and the plurality of gas lines 120. For example, the thermally conductive blocks 131 and 132 may surround the plurality of gas lines 120 and the gas hub 110 at the same time to allow the gas hub 110 and the plurality of gas lines 120 to be heated at the same time by heat conduction.

The heat generating element 133 may be in at least partially contact with the thermally conductive blocks 131 and 132 to heat the thermally conductive blocks 131 and 132, and thus, heat may be transferred to the plurality of gas lines 120 and the gas hub 110 through the thermally conductive blocks 131 and 132 to heat the plurality of gas lines 120 and the gas hub 110. Here, the heat generating element 133 may be in close contact with the thermally conductive blocks 131 and 132 so that the heat is well conducted (or transferred) to the thermally conductive blocks 131 and 132. The heat generating element 133 may be attached to and detached from the thermally conductive blocks 131 and 132 and may be replaced by being coupled to and separated from the thermally conductive blocks 131 and 132.

Here, the thermally conductive blocks 131 and 132 may include a hub accommodation part 131 surrounding the gas hub 110, and a gas line accommodation part 132 surrounding the plurality of gas lines 120. The hub accommodation part 131 may surround the gas hub 110 and cover an entire outer surface of the gas hub 110 and may be in contact with (or be in close contact with) the outer surface of the gas hub 110 to transfer (conduct) the heat of the heat generating element 133, thereby heating the gas hub 110 so as to heat the process gas.

The gas line accommodation part 132 may be coupled (or connected) (integrally) to the hub accommodation part 131 and may surround the plurality of gas lines 120, and each of the gas lines 120 may extend from the hub accommodation part 131 in a direction in which each gas line 120 is branched from the gas hub 110. For example, the gas line accommodation part 132 may surround (or encloses) the hub accommodation part 131 to extend outward (in the direction) from the outer surface (or peripheral surface) of the hub accommodation part 131, thereby surrounding the plurality of gas lines 120 at once and also may be in contact with the outer surface of the hub accommodation part 131 to extend in the branched direction of the gas line 120, thereby surrounding the gas line(s) 120 in the (branched) direction (or the same direction). As a result, the gas line accommodation part 132 may be in close contact with (or in contact with) the outer surface of each of the plurality of gas lines 120 to conduct (or transfer) the heat of the heat generating element 133 to all of the plurality of gas lines 120. Thus, the plurality of gas lines 120 may be heated, and the process gas in the plurality of gas lines 120 may be heated. The gas line accommodation part 132 may be constituted by two blocks, and each block has a groove to match a shape of the gas line 120 so as to be shaped to surround the gas line 120.

Here, the thermally conductive blocks 131 and 132 may contain aluminum (Al) and may be made of an aluminum material that transfers heat quickly. When each of the thermally conductive blocks 131 and 132 is made of aluminum, the heat of the heat generating element 133 may be quickly transferred to the gas hub 110 and the plurality of gas lines 120 due to excellent thermal conductivity of aluminum, and also, processability may be excellent, and the processing (or design) may be easy. For example, the thermally conductive blocks 131 and 132 may be configured (or designed) to surround the gas hub 110 and the plurality of gas lines 120, be processed in a shape that surrounds the gas hub 110 and the plurality of gas lines 120 so as to be assembled with the outsides of the gas hub 110 and the plurality of gas lines 120, be provided so that the gas hub 110 and the plurality of gas lines 120 are disposed (easily) in the thermally conductive blocks 131 and 132, and be made of aluminum to facilitate the design (configuration) of the thermal conductive blocks 131 and 132.

In addition, the heat generating element 133 may include a cartridge heater. The cartridge heater may be installed (or mounted) with at least a portion inserted into the thermally conductive blocks 131 and 132 and thus may be in contact with (an inner surface of) the thermally conductive blocks 131 and 132 to heat the thermally conductive blocks 131 and 132 and also may conduct (transfer) the heat through the thermally conductive blocks 131 and 132 to (directly) the hub 110 and the plurality of gas lines 120. Here, the cartridge heater may be replaced, and specifications such as capacity and quantity of the cartridge heater mounted (or installed) within the thermally conductive blocks 131 and 132 may be determined in accordance with (or suitable for) a size and heating (target) temperature of each of the thermally conductive blocks 131 and 132.

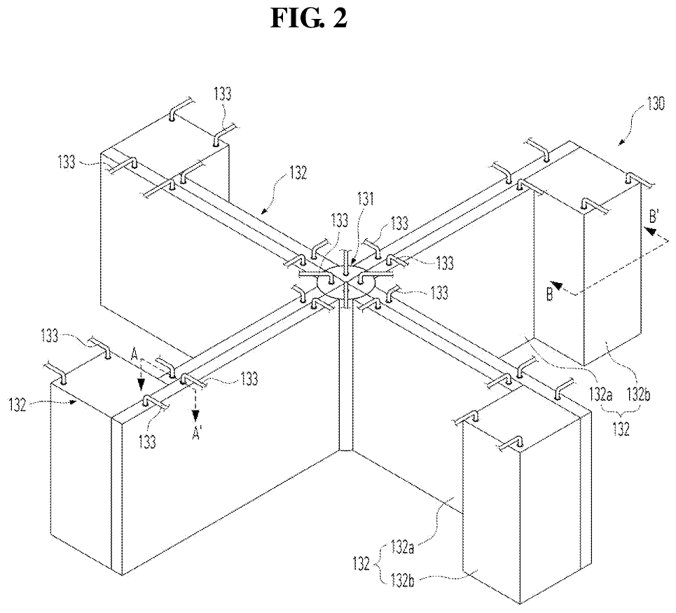

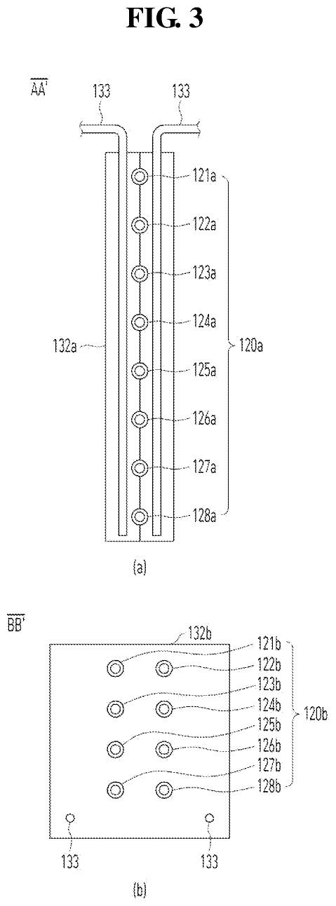

FIG. 2 is a view of the process gas supply device including a plurality of gas hubs in accordance with an exemplary embodiment, and FIG. 3 is a partial cross-sectional view of a first line accommodation part and a second line accommodation part in accordance with an exemplary embodiment. Here, (a) of FIG. 3 is a cross-sectional view of the first line accommodation part, and (b) of FIG. 3 is a cross-sectional view of the second line accommodation part.

Referring to FIGS. 2 and 3, each of the plurality of gas lines 120 may include a horizontal line part 120a extending radially from the gas hub 110 and a vertical line part 120b extending in a direction perpendicular to the radial direction from the horizontal line part 120a. The horizontal line part 120a may be connected to the gas hub 110 to extend radially (or outwardly) from the gas hub 110 and also may extend in the radial direction (e.g., a horizontal direction) toward the corresponding shower head 210 and then be connected to the vertical line part 120b so that each of the plurality of gas lines 120 are connected to the corresponding shower heads 210, respectively.

The vertical line part 120b may be connected to the horizontal line part 120a to extend from the horizontal line part 120a in the direction (e.g., vertical direction) perpendicular to the radial vertical and may extend in the direction perpendicular to the radial direction toward the corresponding shower head 210 so as to be connected to the corresponding shower head 210.

As a result, the process gas branched from the gas hub 110 may flow through the plurality of gas lines 210 and then be supplied to each of the shower heads 210, and thus, the processing process may be independently performed on the substrate 10 in the plurality of sub chambers 215, which are respectively provided in the plurality of shower heads 210.

Here, the gas line accommodation part 132 may include a first line accommodation part 132a that surrounds the horizontal line part 120a and a second line accommodation part 132b that surrounds the vertical line part 120b. The first line accommodation part 132a may surround the horizontal line part 120a and may be connected to (or coupled to) the hub accommodation part 131 to extend in the radial direction along the horizontal line part 120a and transfer the heat of the heat generating element 133 to the horizontal line part 120a.

The second line accommodation part 132b may surround the vertical line part 120b and may be connected to the first line accommodation part 132a to extend in the direction perpendicular to the radial direction along the vertical line part 120b and transfer the heat of the heat generating element 133 to the vertical line part 120b.

Here, the first line accommodation part 132a and the second line accommodation part 132b may be provided to be integrated with each other or may be integrally coupled to each other.

The gas hub 110 may be provided in plurality and thus stacked in a vertical direction (or the direction perpendicular to the radial direction), and the hub accommodation part 131 may surround the plurality of gas hubs 110 together. The gas hub 110 may be provided in plurality, and each of the plurality of gas hubs 110 may be filled with the process gas (independently or individually). Here, each gas hub 110 may be filled with the same gas or different gases. Some groups of gas hub(s) 110 may filled with the same gas, and each of the remaining gas hubs 110 may be filled with a different gas that is not the same as (or different from) the gas filled in the group of gas hub(s) 110. In addition, the plurality of gas hubs 110 may be stacked in the vertical direction (e.g., up and down direction), and at least two or more gas lines 120 may be branched and connected to the gas hubs 110, respectively, and also, each gas hub 110 connected to each gas hub 110 may extend from each gas hub 110 in the radial direction. Thus, there may be no interference between the plurality of gas lines 120, and the process gas may be stably supplied to each of the plurality of shower heads 210. In addition, when the plurality of gas hubs 110 are stacked in the vertical direction, the plurality of gas lines 120 may be branched to extend in the horizontal direction from each gas hub 110, thereby uniformly flowing (being supplied) to each of the gas lines 120 that are respectively branched from the gas hubs 110.

Here, the hub accommodation part 131 may extend in the stacking direction of the plurality of gas hubs 110 to surround the plurality of gas hubs 110 together (or at once), and the plurality of gas hubs 110 may be stacked to extend in the vertical direction along the stacking direction to easily surround the plurality of gas hubs 110 at once. Thus, the plurality of gas hubs 110 may be uniformly heated, the heating uniformity of the plurality of gas hubs 110 may be improved, and the temperature of the process gas filled in each of the plurality of gas hubs 110 may be uniformly and stably maintained in all the gas hubs 110.

Here, the plurality of gas lines 120 may be connected to each gas hub 110, respectively, in the same number, and the gas line accommodation part 132 may be provided in plurality to surround the gas lines 120 that are disposed in the same direction. The plurality of gas lines 120 may be connected to each gas hub 110, respectively, in the same number, and the number of gas lines 120 connected to each gas hub 110 may be may be the same as that of plurality of shower heads (through which the process gas is injected to the different substrates), and the processing process may be performed while the process gas is supplied (or injected) to each of the substrates 10.

In addition, the gas line(s) 120 extending from each of (different) gas hubs 110 and connected to the same shower head 210 may also be stacked in the vertical direction like the plurality of gas hubs 110, and the gas line accommodation part 132 may surround the vertically stacked gas lines 120 in the same direction at once (or together) and be provided in plurality to surround the gas lines 120 in the same direction. The gas line accommodation part 132 may extend in the vertical direction (or the stacking direction of the gas line(s) in the same direction) to surround two or more gas lines 120 together, which extend in the same direction, and thus, the plurality of gas lines 120 may be heated uniformly to improve the heating uniformity of the plurality of gas lines 120, and the temperature of the process gas filled in each of the plurality of gas lines 120 may be maintained uniformly and stably at all the points of the plurality of gas lines 120.

When the gas line(s) 120 in the same direction are stacked in the vertical direction, the first line accommodation part 132a and the second line accommodation part 132b may have different shapes. For example, the first line accommodation part 132a may have a (relatively) long length in the extension direction of the horizontal line part 120a of the gas line(s) 120 that are disposed in the same direction as the vertical direction in which the horizontal line part 120a of the gas line(s) 120 in the same direction are stacked and may have a (relatively) narrow (small) width (or length) in a direction crossing the vertical direction and the extension direction, and the second line accommodation part 132b may have a (relatively) long length in the vertical direction in which the vertical line part 120b of the gas line 120(s) in the same direction extends and may have a (relatively) small (narrow) length (or width) in the (two) crossing direction (e.g., a forward and backward direction and left and right direction) crossing the vertical direction. Additional one or more (e.g., four) auxiliary blocks may be inserted into a space between the gas lines 120 of the main block in the second line accommodation part 132b to improve heat conduction efficiency and also improve heat conduction of the thermally conductive blocks 131 and 132.

As illustrated in FIGS. 2 and 3, the first line accommodation part 132a may have a rectangular parallelepiped shape in which a rectangular shape that is long in the vertical direction and has a small (or narrow) width in a direction crossing the vertical direction and the extension direction extends in the extension direction, and the second line accommodation part 132b may have a rectangular parallelepiped shape in which a square having a width in the (two) crossing direction so that the vertical line part 120b is maintained at a similar (or the same) distance as a center of each corresponding shower head 210 extends in the vertical direction. Here, the vertical line parts 120b of the gas line(s) 120 in the same direction may be disposed symmetrically with respect to the center of each of the corresponding shower heads 210 and may have the same distance from the center of the corresponding shower head 210, and the second line accommodation part 132b may be provided to be in contact with a surface in the direction crossing the vertical direction and the extension direction of the first line accommodation part 132a as illustrated in FIG. 2, but the surface in the extension direction of the first line accommodation part 132a.

As a result, even when the process gas includes a plurality of gases, all the gases may be stably supplied to each corresponding shower head 210 to improve uniformity of each gas.

The horizontal line part 120a may include a first horizontal line 121a, a second horizontal line 122a, a third horizontal line 123a, a fourth horizontal line 124a, a fifth horizontal line 125a, a sixth horizontal line 126a, a seventh horizontal line 127a, and an eighth horizontal line 128a, and the first horizontal line 121a, the second horizontal line 122a, the third horizontal line 123a, the fourth horizontal line 124a, the fifth horizontal line 125a, the sixth horizontal line 126a, the seventh horizontal line 127a, and the eighth horizontal line 128a may be stacked in the vertical direction and may be accommodated in the first line accommodation part 132a.

In addition, the vertical line part 120b may include a first vertical line 121b, a second vertical line 122b, a third vertical line 123b, a fourth vertical line 124b, a fifth vertical line 125b, a sixth vertical line 126b, a seventh vertical line 127b, and an eighth vertical line 128b, and the first vertical line 121b, the second vertical line 122b, the third vertical line 123b, the fourth vertical line 124b, the fifth vertical line 125b, the sixth vertical line 126b, and the seventh vertical line 121b may be disposed to be spaced a similar distance from a center of the corresponding shower head 210 and be accommodated in the second line accommodation part 132b.

Here, the plurality of gas supply lines 21 that supply the process gas may be connected to the plurality of gas hubs 120, and the process gas may include a plurality of gases supplied to different gas hubs 110. The plurality of gas supply lines 21 that supply the process gas from the gas supply source (not shown) may be connected to the plurality of gas hubs 120, respectively, and the gas supply lines 21 that are different from each other may be connected to the gas hubs 120, respectively, and thus, the gas may be filled independently into each of the gas hubs 120.

Here, the process gas may include a plurality of gases supplied to different gas hubs 110, and the plurality of gases may be the same as or different from the number of gas hubs 110, but two or more gas hubs are sufficient. For example, the plurality of gases may be different from each other, and at least one of the type or function of the gas may be different from each other. When the number of gases and the number of gas hubs 110 are the same, each gas hub 110 may be filled with one gas through each gas supply line 21, and when the number of gas hubs 110 is greater than the number of gases, some of the plurality of gases may be supplied to two or more gas hubs 110 while each gas is supplied to at least one gas hub 110. In this case, each gas may be supplied to each of the gas hubs 110 through each of the gas supply lines 21.

In addition, the plurality of gas lines 120 may be symmetrical to each other about the gas hub 110 to extend radially, and a length (or extension length) from the gas hub 110 to the corresponding shower head 210 may be the same. The plurality of shower heads 210 may also be disposed symmetrically around the gas hub 110 so that the lengths of the plurality of gas lines 120 from the gas hub 110 to the corresponding shower heads 210 are the same, and thus, the (same) process gas may be uniformly supplied to each of the plurality of shower heads 210 so that the process uniformity (or processing uniformity) is improved between a plurality of sub chambers 215 in which the plurality of shower heads 210 are provided, respectively.

The process gas may include a source gas S, a reactant gas R that reacts with the source gas, a source purge gas SP that purges the source gas, and a reactive purge gas RP that purges the reactant gas. For example, the source gas may include titanium tetrachloride (TiCl₄) and dichlorosilane DCS (SiH₂Cl₂), and the reactant gas may include ammonia (NH₃) and hydrogen (H₂). In addition, each of the source purge gas and the reactant purge gas may be an inert gas, may include nitrogen (N₂), hydrogen (H₂), and argon (Ar), and may be the same type (or the same) gases or a different type (or different) gas.

The process gas supply device 100 in accordance with an exemplary embodiment may further include a temperature measuring part (not shown) that measures a temperature of each of the thermally conductive blocks 131 and 132.

The temperature measuring part (not shown) may measure the temperature of each of the thermally conductive blocks 131 and 132 and control the temperatures of the thermally conductive blocks 131 and 132 by measuring the temperatures of the thermally conductive blocks 131 and 132. Here, the temperature measuring part (not shown) may include a temperature sensor such as a thermocouple.

For example, the process gas supply device 100 in according to an exemplary embodiment may further include a control part (not shown) that controls the heat generating element 133 to adjust the temperatures of the thermally conductive blocks 131 and 132. The thermally conductive blocks 131 and 132 may be divided into a plurality of (e.g., nine) zones, and each zone may be controlled to a target temperature (or required temperature) through the control part (not shown). Here, the control part (not shown) may reads a temperature of each zone through the temperature measuring part (not shown) to control an output (e.g., output energy or energy emission intensity) of the heat generating element 133 so as to reach the control temperature (or target temperature). Here, the temperatures of the thermally conductive blocks 131 and 132 may be read using thermocouples installed outside the thermally conductive blocks 131 and 132, and a control thermocouple and a monitor thermocouple may be installed in each zone. The control thermocouple may be used to control the temperatures of the thermally conductive blocks 131 and 132, and the monitor thermocouple may be used to detect abnormal temperatures to operate an automatic locking device such as an interlock. The plurality of zones may be a heater zone or heating zone in which the heat generating element 133 is disposed.

In addition, the control part (not shown) may include a heater temperature controller (HTC), which compares the current temperature to the control temperature of each zone to control the target temperature by adjusting an operation time of a non-contact relay (breaker), etc. such as a solid state relay (SSR). A set temperature of the heating zone may be different for each zone and may be determined from approximately 100° C. to approximately 180° C., and the two thermocouples may be installed in each heating zone. Here, the control thermocouple may be connected to the heater temperature controller and may be used to control the temperatures of the thermally conductive blocks 131 and 132, and the monitor thermocouple may be connected to a process device controller (PDC) to operate the interlock relay when the an abnormal temperature is detected.

For example, the hub accommodation part 131 may connect four cartridge heaters in series to define one heating zone, and a K-type thermocouple may be assembled to a lower portion of each of the thermally conductive blocks 131 and 132 to control a temperature of the hub accommodation part 131. In addition, the first line accommodation part 132a may connect five cartridge heaters in series to define one heating zone and also define a plurality of (e.g., four) heating zones in each direction, and the K-type thermocouple may be assembled to the outside of each of the thermally conductive blocks 131 and 132 to control a temperature of the first line accommodation part 132a. In addition, the second line accommodation part 132b may connect four cartridge heaters in series to define one heating zone and also define a plurality of (e.g., four) heating zones in each direction, and the K-type thermocouple may be assembled to a side surface of each of the thermally conductive blocks 131 and 132 to control a temperature of the second line accommodation part 132b.

In addition, the integrated heater part 130 may further include an insulating part surrounding the thermally conductive blocks 131 and 132. The insulating part may surround the thermally conductive blocks 131 and 132 and prevent heat from being lost to the outside of the thermally conductive blocks 131 and 132.

The insulating part may include glass fiber and may surround the thermally conductive blocks 131 and 132 with an insulator made of glass fiber.

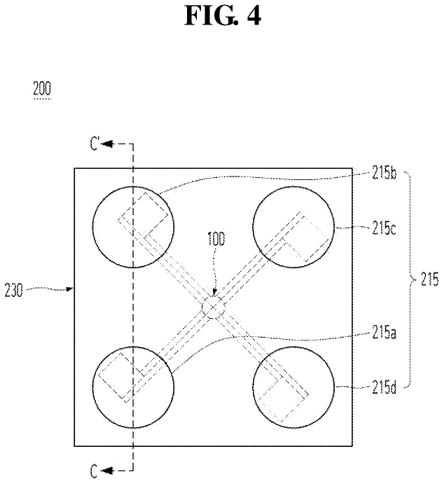

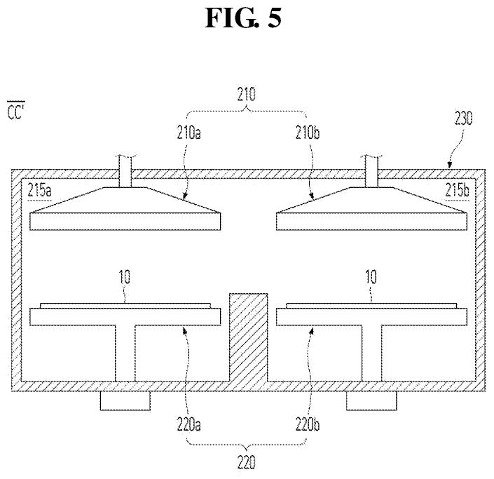

FIG. 4 is a schematic view of a substrate processing system in accordance with another exemplary embodiment, and FIG. 5 is a cross-sectional view of a plurality of sub chambers in accordance with another exemplary embodiment.

A substrate processing system in accordance with another exemplary embodiment will be described with reference to FIGS. 4 to 5. In the description of the process gas supply device in accordance with another exemplary embodiment, duplicated descriptions with respect to the process gas supply device in accordance with an exemplary embodiment will be omitted.

A substrate processing system 200 in accordance with another exemplary embodiment may include the process gas supply device 100 in accordance with an exemplar embodiment, a plurality of shower heads that are branched from the gas hub 110 so that the process gas is applied thereto, and a plurality of substrate supports 220 provided to correspond to the plurality of shower heads 210.

The process gas supply device 100 may be the process gas supply device 100 in accordance with an exemplary embodiment and may supply the process gas having a uniform temperature to each of the plurality of shower heads 210, as described above in detail.

The plurality of shower heads 210 may be branched from the gas hub 110 to supply the process gas, may inject the process gas for the substrate processing onto the substrate 10, and may be provided in the sub chambers 215, respectively.

The plurality of substrate supports 220 may be respectively provided to correspond to the plurality of shower heads 210 to support the substrate 10 to be processed, may be respectively provided in the sub chambers 215, and may inject the process gas onto the substrate supported on the substrate support 220 to perform substrate processing such as deposition.

The substrate processing system 200 in accordance with an exemplary embodiment may further include a plurality of sub chambers 215 in which the plurality of shower heads 210 and the plurality of substrate supports 220 are respectively provided in pairs.

The plurality of sub chambers 215 may be respectively provided in pairs of the plurality of shower heads 210 and the plurality of substrate supports 220 and may perform processes on the plurality of substrates 10 (at the same time). Each sub chamber 215 may perform the processing process on each substrate 10. Here, the plurality of sub chambers 215 may be spatially separated (or isolated) by a partition, etc. to constitute a chamber module and may be divided into a plurality of sub chambers 215 (e.g., a first sub chamber, a second sub chamber, a third sub chamber, and a fourth sub chamber) in which processes are independently performed only regionally within a chamber wall 230 to constitute the chamber module. For example, the first sub chamber 215a, second sub chamber 215b, third sub chamber 215c, and fourth sub chamber 215d, which are provided in the chamber wall 230 of the chamber module, may be divided only regionally within the chamber wall 230 to communicate with each other, but may not be spatially separated by partitions, etc.

The processes may be performed independently in the first sub chamber 215a, the second sub chamber 215b, the third sub chamber 215c, and the fourth sub chamber 215d, may have the same configuration as the shower head 210 and the substrate support 200, and may be numbered in terms of locations (or areas).

For example, the first sub chamber 215a may include a first substrate support 220a on which a first substrate 10 is supported, and a first shower head 210a provided on the first substrate support 220a to inject a gas for substrate processing onto the first substrate 10 supported on the first substrate support 220a, and the second sub chamber 215b may include a second substrate support 220b on which a second substrate 10 is supported, and a second shower head 210b provided on the second substrate support 220b to inject a gas for substrate processing onto the second substrate 10 supported on the second substrate support 220b.

Each of the first shower head 210a and the second shower head 210b may be connected to the gas line 120, and the first shower head 210a and the second shower head 210b may be provided to the first sub chamber 215a and the second sub chamber 215b, respectively, and thus, one of the plurality of gases may be selectively supplied, and the supplied process gas may be injected. Here, the same gas or different gases may be supplied to the first shower head 210a and the second shower head 210b.

In addition, the first substrate support 220a and the second substrate support 220b may be provided in the first sub chamber 215a and the second sub chamber 215b to support the first substrate 10 and the second substrate 10, respectively. As a result, the processing of the plurality of substrates 10 may be performed at the same time in one chamber module, and thus, process yield may be improved.

Here, the plurality of shower heads 210 may be disposed symmetrical to each other and may also be disposed symmetrically around the gas hub 110 so that the lengths of the plurality of gas lines 120 from the gas hub 110 to the corresponding shower heads 210 are the same, and thus, the (same) process gas may be uniformly supplied to each of the plurality of shower heads 210 so that the process uniformity (or processing uniformity) is improved between a plurality of sub chambers 215 in which the plurality of shower heads 210 are provided, respectively.

In addition, each gas hub 110 may be supplied with any one of the process gases. That is, only one gas may be supplied to the gas hub 110, the supplied gas may not be changed, and the plurality of gases may react within the gas hub 110, the gas line 120, and/or the shower head 210 to prevent particles, etc. from being generated during the process.

The plurality of gases may be selectively supplied to the first sub chamber 215a, the second sub chamber 215b, the third sub chamber 215c, and the fourth sub chamber 215d, and also, the plurality of gases may be divided to be supplied to the first sub chamber 215a, the second sub chamber 215b, the third sub chamber 215c, and the fourth sub chamber 215d, respectively. In general, the same gas may be supplied to all the first sub chamber 215a, the second sub chamber 215b, the third sub chamber 215c, and the fourth sub chamber 215d, but the plurality of gases may be divided so that different gases are supplied to the first sub chamber 215a, the second sub chamber 215b, the third sub chamber 215c, and the fourth sub chamber 215d, respectively, or gases, which are different from the gases supplied to other sub chamber(s) are supplied to at least one of the first sub chamber 215a, the second sub chamber 215b, the third sub chamber 215c, or the fourth sub chamber 215d. Here, the number of gas hubs 110 may be the same as the number of plurality of gases or the number of sub chambers 215, and also, the number of sub chambers 215 and the number of plurality of gases may be the same.

Thus, in the substrate processing system 200 in accordance with an exemplary embodiment, the process gas supply device 100 in accordance with an exemplary embodiment may be applied to the plurality of sub chambers 215 provided (or constituted) by the plurality of shower heads 210 and the plurality of substrate supports 220, and thus, each of the plurality of gas lines 120, each of which is branched from the gas hub 110 and connected to the plurality of shower heads 210, may be uniformly heated to supply the process gas having the uniform temperature to the plurality of shower heads 210, respectively, to improve the process uniformity between the plurality of sub chambers 215 and perform the excellent quality substrate processing on the plurality of substrates at the same time.

As such, in the present disclosure, the gas sub and the plurality of gas lines may be heated at the same time through the integrated heater part by surrounding the plurality of gas lines and the gas hub together to improve the heating uniformity of the plurality of gas lines, thereby uniformly and stably maintain the process gas at the all points. Therefore, the particles generated during the process due to the limitations such as changes in the temperature of the process gas in the specific portion may be prevented, and the stable reaction of the process gas may be achieved. In addition, when applying the process gas supply device to the substrate processing system in which the plurality of shower heads and the plurality of substrate supports constitute the plurality of sub chambers, each of the plurality of gas lines branched from the gas hub and respectively connected to the plurality of shower heads may be heated uniformly to supply the process gas having the uniform temperature to the plurality of shower heads, and thus, the process uniformity between the plurality of sub chambers may be improved, and the excellent quality substrate processing may be performed on the plurality of substrates at the same time.

The process gas supply device in accordance with the exemplary embodiment may heat the gas sub and the plurality of gas lines at the same time through the integrated heater part by surrounding the plurality of gas lines and the gas hub together to improve the heating uniformity of the plurality of gas lines, thereby uniformly and stably maintain the process gas at the all points. Therefore, the particles generated during the process due to the limitations such as changes in the temperature of the process gas in the specific portion may be prevented, and the stable reaction of the process gas may be achieved.

In addition, when applying the process gas supply device to the substrate processing system in which the plurality of shower heads and the plurality of substrate supports constitute the plurality of sub chambers, each of the plurality of gas lines branched from the gas hub and respectively connected to the plurality of shower heads may be heated uniformly to supply the process gas having the uniform temperature to the plurality of shower heads, and thus, the process uniformity between the plurality of sub chambers may be improved, and the excellent quality substrate processing may be performed on the plurality of substrates at the same time.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

What is claimed is:

1. A process gas supply device comprising:
a gas hub to which a process gas is supplied from a gas supply source;
a plurality of gas lines branched from the gas hub to transfer the supplied process gas; and
an integrated heater part provided to surround the plurality of gas lines and the gas hub so as to heat the gas hub and the plurality of gas lines at the same time.

2. The process gas supply device of claim 1, wherein the integrated heater part comprises:
a thermally conductive block configured to surround the plurality of gas lines and the gas hub; and
a heat generating element that is in at least partially contact with the thermally conductive block to heat the thermally conductive block.

3. The process gas supply device of claim 2, wherein the thermally conductive block comprises:
a hub accommodation part configured to surround the gas hub; and
a gas line accommodation part configured to surround the plurality of gas lines.

4. The process gas supply device of claim 3, wherein each of the plurality of gas lines comprises a horizontal line part extending in a radial direction from the gas hub and a vertical line part extending in a direction perpendicular to the radial direction,
wherein the gas line accommodation part comprises:
a first line accommodation part configured to surround the horizontal line part; and
a second line accommodation part configured to surround the vertical line part.

5. The process gas supply device of claim 4, wherein the first line accommodation part and the second line accommodation part have shapes different from each other.

6. The process gas supply device of claim 3, wherein the gas hub is provided in plurality to be stacked in a vertical direction, and
the hub accommodation part is configured to surround the plurality of gas hubs together.

7. The process gas supply device of claim 6, wherein the plurality of gas lines are connected to each of the gas hubs, respectively, in the same number, and
the gas line accommodation part is provided in plurality to surround the gas lines disposed in the same direction.

8. The process gas supply device of claim 6, wherein a plurality of gas supply lines through which the process gas is supplied are connected to the plurality of gas hubs, respectively, and
the process gas comprises a plurality of gases supplied to the gas hubs different from each other.

9. The process gas supply device of claim 1, wherein the plurality of gas lines are disposed symmetrically around the gas hub to extend radially.

10. The process gas supply device of claim 2, wherein the thermally conductive block comprises aluminum.

11. The process gas supply device of claim 2, wherein the heat generating element comprises a cartridge heater.

12. The process gas supply device of claim 2, further comprising a temperature measuring part configured to measure a temperature of the thermally conductive block.

13. The process gas supply device of claim 2, wherein the integrated heater part further comprises an insulating part configured to surround the thermally conductive block.

14. The process gas supply device of claim 13, wherein the insulating part comprises glass fiber.

15. A substrate processing system comprising:
the process gas supply device of claim 1;
a plurality of shower heads which are branched from the gas hub and into which the process gas is supplied; and
a plurality of substrate supports provided to correspond to the plurality of shower heads, respectively.

16. The substrate processing system of claim 15, further comprising a plurality of sub chambers in which the plurality of shower heads and the plurality of substrate supports are respectively provided in pairs.

17. The substrate processing system of claim 15, wherein the plurality of shower heads are disposed to be symmetrical to each other.

18. The substrate processing system of claim 15, wherein each of the gas hubs is supplied with any one of the process gas.
